(19) United States
(12) Patent Application Publication
(10) Pub. No.: US 2010/0200042 A1
(43) Pub. Date: Aug. 12, 2010

(54) PHOTOVOLTAIC DEVICE AND METHOD FOR MANUFACTURING PHOTOVOLTAIC DEVICE

(75) Inventor: Toshio Yagiura, Hyogo (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi, Osaka (JP)

(21) Appl. No.: 12/679,605

(22) PCT Filed: Sep. 2, 2009
(86) PCT No.: PCT/JP2009/065340

§ 371 Date: Mar. 23, 2010

(30) Foreign Application Priority Data
Sep. 10, 2008 (JP) 2008-231951

(51) Int. Cl. H01L 31/042; H01L 21/326

(52) U.S. Cl. 136/244; 438/88; 257/E21.327

(57) ABSTRACT

A method for manufacturing a photovoltaic device including one or a plurality of photovoltaic cells is provided. Each of the photovoltaic cells includes a transparent conductive film, a photovoltaic layer, and a metal electrode which are formed on a substrate. A voltage is applied between a first portion of the metal electrode and a second portion of the metal electrode that is distant from the first portion, so as to remove at least apart of the metal electrode.

### TECHNICAL FIELD

The present invention relates to photovoltaic devices and methods for manufacturing photovoltaic devices.

### BACKGROUND ART

Solar cells using polycrystalline, microcrystalline, or amorphous silicon have been known. In a common process of fabricating solar cells, after a transparent conductive film of tin oxide (SnO₂) or the like is formed on a glass substrate, polycrystalline, microcrystalline, or amorphous silicon constituting a photovoltaic layer is deposited by chemical vapor deposition (CVD) or the like. Then, an electrode serving as a backside electrode is formed. The electrode is formed by means of, for example, depositing a conductive material such as aluminum (Al), silver (Ag), or titanium (Ti) by vacuum deposition or sputtering.

However, when forming such an electrode layer, the metal may be provided to the backside of the glass substrate, which is opposite to the surface where the photovoltaic layer has been formed and the electrode layer is to be formed. This causes a problem of deterioration in insulation resistance between the backside electrode of the solar cell and the surface of the glass substrate, for example.

As such, in order to prevent formation of a film reaching the backside of the film forming surface of a substrate, a method for reducing a gap between the substrate and a substrate holder (tray) for mounting the substrate has been proposed (JP 2007-197745 A, and the like).

There is also a problem that when repeating the process of forming electrode layers, deposits to a substrate holder may fall off during formation of the electrode layers and be taken into the electrode layers. To prevent the deposits from falling off, measures such as keeping the substrate holder at a high temperature must be taken. As such, in order to reduce impurity intake from the substrate holder when forming the electrode layers, a holder-less method (tray-less method) has tended to be adopted.

### DISCLOSURE OF THE INVENTION

### Problems to be Solved by the Invention

However, in the case of adopting a holder-less method, a metal layer may reach the glass substrate side, which has been protected by the substrate holder, so that an electrode layer may be formed on the backside of the film forming surface of the photovoltaic layer. For example, as shown in FIG. 9, when forming an electrode layer by sputtering or the like while conveying a substrate 14 with a photovoltaic layer formed thereon by rollers 10 and 12 in a direction orthogonal to the extending direction of the rollers 10 and 12, the electrode layer may be formed reaching the glass substrate side by wrapping the edges 14a and 14b in the conveying direction of the substrate 14.

If the electrode layer is formed reaching the backside as described above, the dielectric strength feature between the electrode layer and the glass substrate may be deteriorated.

Further, even for the electrode layer formed on the photovoltaic layer side, when the photovoltaic device is modularized, an electrode portion formed near an end part of the substrate is to be positioned near the metal frame which is a structure of the module, so the electrode portion may deteriorate the dielectric strength of the module.

### Means for Solving the Problems

An aspect of the present invention is a method for manufacturing a photovoltaic device including one or a plurality of photovoltaic cells, each of the photovoltaic cells including a first electrode layer, a semiconductor layer, and a second electrode layer which are formed on a substrate. The method includes applying a voltage between a first portion of the second electrode layer in which a photovoltaic power is not obtained, and a second portion of the second electrode layer which is distant from the first portion, and in which a photovoltaic power is not obtained, so as to remove at least a part of the second electrode layer.

### BRIEF DESCRIPTION OF THE DRAWINGS

FIG. 1 is a cross-sectional view illustrating a manufacturing process of a photovoltaic device according to an embodiment of the present invention.

FIG. 2 is a view illustrating a method for manufacturing the photovoltaic device according to an embodiment of the present invention.

FIG. 3 is a view illustrating the method for manufacturing the photovoltaic device according to an embodiment of the present invention.

FIG. 4 is a view illustrating the method for manufacturing the photovoltaic device according to an embodiment of the present invention.

FIG. 5 is a view illustrating the method for manufacturing the photovoltaic device according to an embodiment of the present invention.

FIG. 6 is an enlarged perspective view illustrating the configuration of the photovoltaic device according to an embodiment of the present invention.

FIG. 7 is a cross-sectional view illustrating the overall configuration of the photovoltaic device according to an embodiment of the present invention.

FIG. 8 is a view illustrating another exemplary method for manufacturing the photovoltaic device according to an embodiment of the present invention.

FIG. 9 is a view illustrating a method for manufacturing a photovoltaic device according to the background art.

### DESCRIPTION OF EMBODIMENTS

A method for manufacturing a photovoltaic device according to an embodiment of the present invention will be described below. In the present embodiment, description will be exemplarily given according to a tandem thin-film photovoltaic device using an amorphous silicon film (a-Si film) and a microcrystalline silicon film (μc-Si film). However, the applicable range of the present invention is not limited to this embodiment, and the present invention is applicable to various photovoltaic devices including single-layered, multilayered, thin-film type, and bulk-type devices.

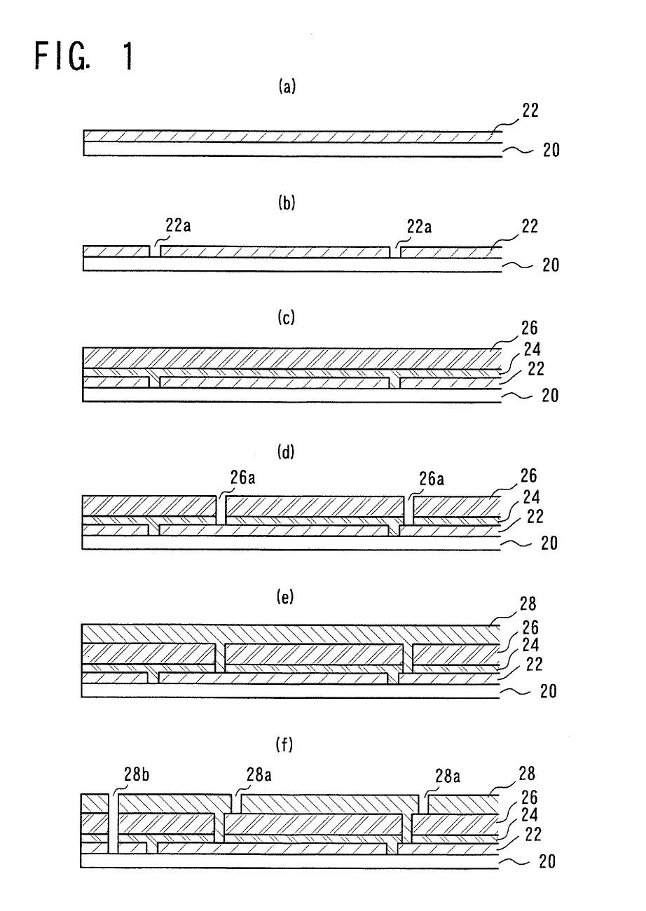

First, a transparent conductive film 22 is formed as a first electrode on a substrate 20 (FIG. 1(a)). As the substrate 20, a transparent insulating material such as glass or plastic may be used. The transparent conductive film 22 is formed of tin oxide (SnO₂), zinc oxide (ZnO), or the like, by thermal chemical vapor deposition (thermal CVD) or the like.

Next, slits 22a are formed in the transparent conductive film 22 by a laser separation process, whereby the transparent conductive film 22 is separated into rectangles (FIG. 1(b): the slits 22a are formed in a direction vertical to the sheet surface). For the laser separation process, it is preferable to use a Nd:YAG laser having a wavelength of about 1.06 μm, an energy density of 13 J/cm³, and a pulse frequency of 3 kHz, for example.

After the laser separation process, an a-Si film 24 and a μc-Si film 26, serving as photovoltaic layers (power generating layers), are formed on the transparent conductive film 22 in this order, each including a p-layer, an i-layer, and an n-layer (FIG. 1(c)). The a-Si film and the μc-Si film may be formed by plasma chemical vapor deposition (P-CVD). Table 1 shows examples of deposition conditions for this process.

TABLE 1

| | | | | | | Film |
|---|---|---|---|---|---|---|
| | | Substrate | Gas Flow | Reaction | RF | Thick- |
| | | Temperature | Rate | Pressure | Power | ness |
| Film | | (° C.) | (sccm) | (Pa) | (W) | (nm) |
| a-Si | p-layer | 180 | SiH4: 300 | 106 | 10 | 10 |
| | | | CH4: 300 | | | |
| | | | H2: 2000 | | | |
| | | | B2H6: 3 | | | |
| | i-layer | 200 | SiH4: 300 | 106 | 20 | 300 |
| | | | H2: 2000 | | | |
| | n-layer | 180 | SiH4: 300 | 133 | 20 | 20 |
| | | | H2: 2000 | | | |
| | | | PH3: 5 | | | |
| μc-Si | p-layer | 180 | SiH4: 10 | 106 | 10 | 10 |
| | | | H2: 2000 | | | |
| | | | B2H6: 3 | | | |
| | i-layer | 200 | SiH4: 100 | 133 | 20 | 2000 |
| | | | H2: 2000 | | | |
| | n-layer | 200 | SiH4: 10 | 133 | 20 | 20 |
| | | | H2: 2000 | | | |
| | | | PH3: 5 | | | |

Next, slits 26a are formed by applying a laser separation process to the photovoltaic layers 24 and 26 at positions beside the slits 22a of the transparent conductive film 22 processed in rectangles, whereby the photovoltaic layers 24 and 26 are separated into rectangles (FIG. 1(d)). For example, a position 50 μm away from the slit 22a of the transparent conductive film 22 is processed to be separated along the slit 22a of the transparent conductive film 22. For this laser separation process, it is preferable to use a Nd:YAG laser having a wavelength of about 1.06 μm, an energy density of 0.7 J/cm³, and a pulse frequency of 3 kHz, for example.

Then, a metal electrode 28 is formed as a second electrode on the photovoltaic layer 26 (FIG. 1(e)). It is preferable that the metal electrode 28 is mainly made of silver (Ag), for example. The metal electrode 28 may be formed by sputtering. The film thickness of the metal electrode 28 is preferably 200 nm, for example.

In this process, if sputtering is performed in a state where the substrate 20 is mounted on a substrate holder, deposits adhering to the substrate holder may be taken into the metal electrode 28. As such, as shown in FIG. 9, it is preferable to adopt a holder-less method (tray-less method) in which the metal electrode 38 is formed while conveying the substrate 20 by the rollers 10 and 12.

Next, slits 28a are formed by applying a laser separation process to the metal electrode 28 at positions beside the slits 26a of the photovoltaic layer 26 processed to be rectangles, whereby the metal electrode 28 is separated into rectangles (FIG. 1(f)). For example, a position 50 μm away from the slit 26a of the photovoltaic layer 26, in a direction opposite to the slit 22a of the transparent conductive film 22, is processed to be separated along the slit 26a of the photovoltaic layer 26. For this laser separation process, it is preferable to use a Nd:YAG laser having a wavelength of about 1.06 μm, an energy density of 0.7 J/cm³, and a pulse frequency of 4 kHz, for example.

Also, a slit 28b is formed by applying a laser separation process to a position near an end part of the substrate 20. The slit 28b is formed so as to penetrate the transparent conductive film 22, the photovoltaic layers 24 and 26, and the metal electrode 28. With the slit 28b, an ineffective portion not contributing to power generation is formed in an end region of the substrate 20.

Through these processes, the base structure of the integrated photovoltaic device is completed, in which a plurality of solar cells separated by the slits 28a are connected in series.

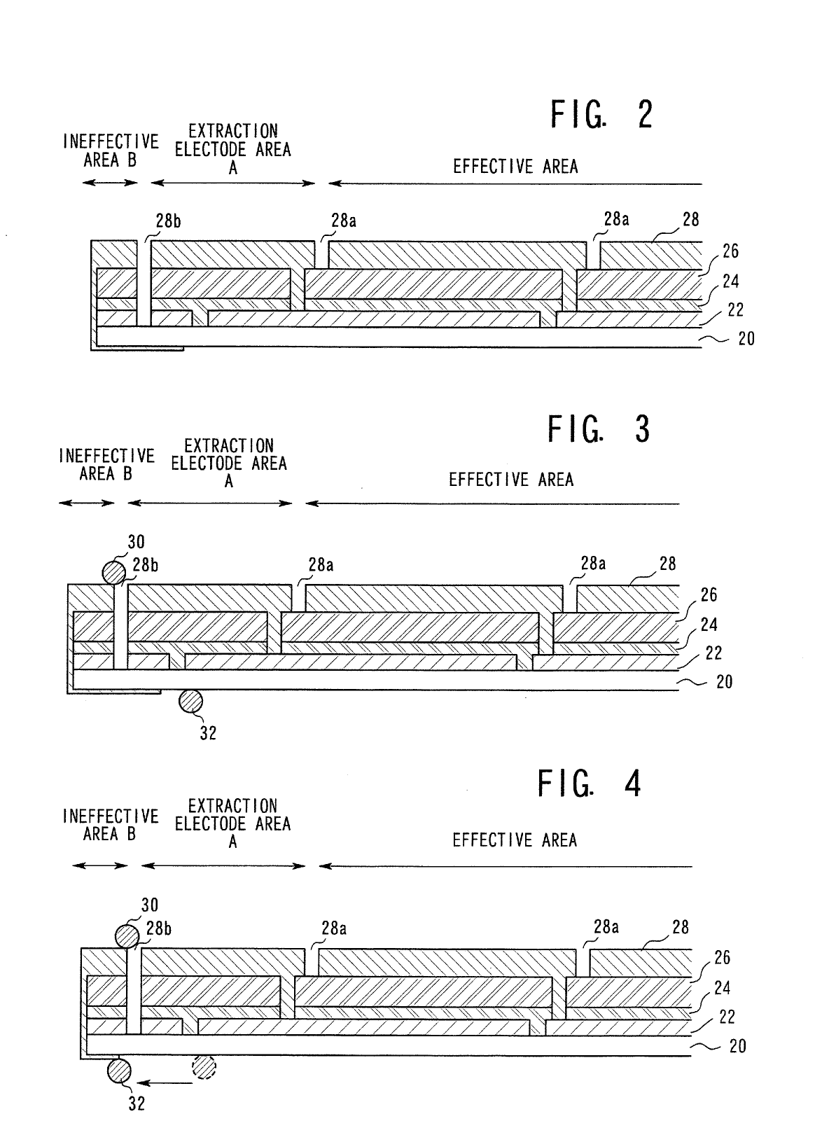

It should be noted that if a holder-less method (tray-less method) is adopted to form the metal electrode 28, the metal electrode 28 may reach the substrate 20 side so that the metal electrode 28 may also be formed on the side face and the surface of the substrate 20, as shown in the cross-sectional view of FIG. 2.

As such, in the present embodiment, a process of removing the metal electrode 28 formed by reaching the surface side of the substrate 20 is performed. As shown in FIG. 3, an electrode bar 30 which is a conductive member is arranged at a position slightly away from an extraction electrode area A and contacting an ineffective area B of the photovoltaic device. Also, another electrode bar 32 is arranged at a position away from the metal electrode 28 reaching the surface of the substrate 20.

While the electrode bars 30 and 32 maybe made of any conductive member, copper, for example, is preferable for their material. Further, as it is desirable to be able to arrange the electrode bars 30 and 32 over an edge of the substrate 20, the length thereof is preferably the same as or longer than the width of the substrate 20. Further, while the electrode bars 30 and 32 maybe in a columnar, cylindrical, or prismatic shape for example, it is more preferable that the electrode bars 30 and 32 are in a shape with a curved surface which linearly contacts the metal electrode 28.

Next, a voltage is applied between the electrode bars 30 and 32. The voltage to be applied is preferably at least higher than the electromotive force of the solar cells (photovoltaic cells). This means that the voltage is preferably of a level at which the metal electrode 28 evaporates by the Joule heat generated by the current flowing in the electrode bars 30 and 32. For example, the voltage is preferably not less than 100 V and not more than 5000 V.

To apply the voltage, it is preferable to use a device with a protection circuit which senses supply current and stops application of the voltage when current larger than a predetermined value flows, such as a withstand voltage test device, for example.

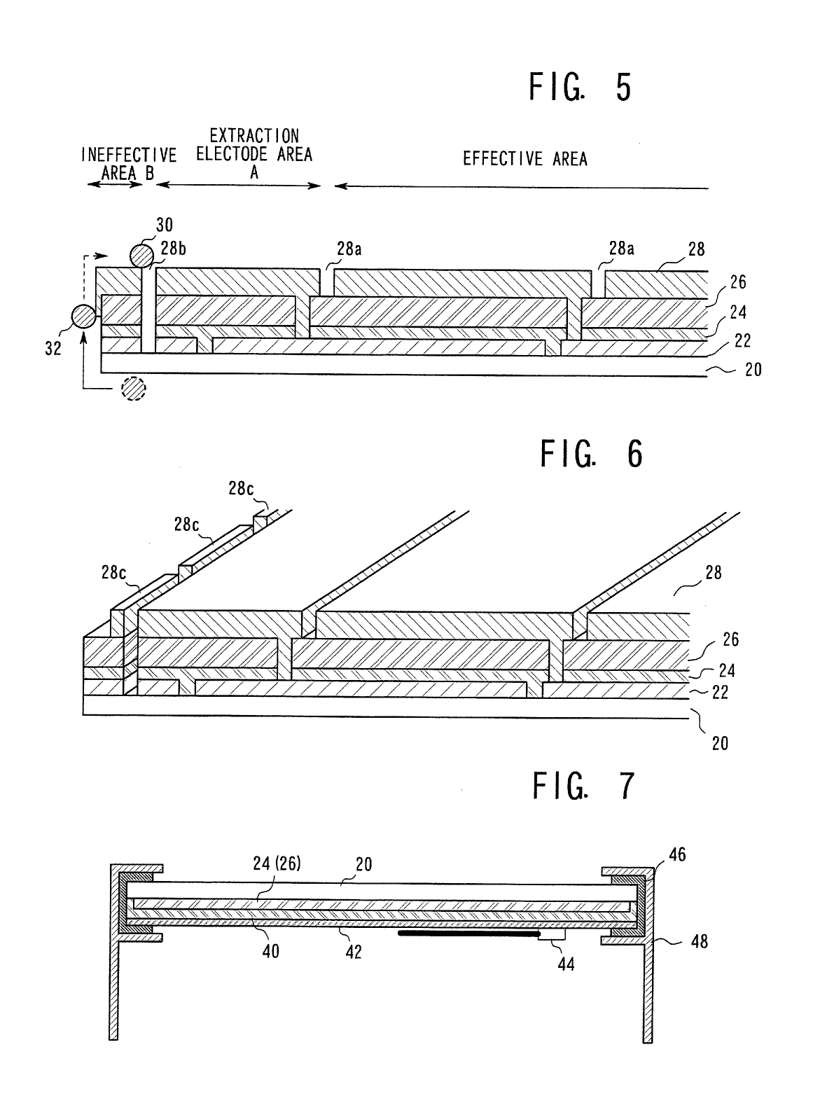

From this state, the electrode bar 32 is gradually moved toward the end part of the substrate 20 while contacting the surface of the substrate 20 or the surface of the metal electrode 28 formed by reaching the surface of the substrate 20, as shown in FIG. 4. Thereby, current flows between the electrode bars 30 and 32, and the metal electrode 28 evaporates by the Joule heat generated by the current. By continuing this process from the surface side to the side face of the end portion of the substrate 20 and to the photovoltaic layer 26 side, excess metal electrode 28 can be removed as shown in FIGS. 4 and 5.

As a voltage is applied between the electrode bars 30 and 32, it is preferable to move the electrode bar 32 to the extent that the electrode bars 30 and 32 do not contact each other. As such, as shown in the perspective view of FIG. 6, although apart of the surface of the photovoltaic layer 26 is not covered with the metal electrode 28 and a metal electrode 28 c corresponding to the gap between the electrode bars 30 and 32 remains in an island shape on the end part of the substrate 20 of the photovoltaic device, the dielectric strength of the photovoltaic device can be improved.

It should be noted that in the present embodiment, although the case of moving the electrode bar 32 has been described, it is acceptable to fix the electrode bar 32 and move the electrode bar 30. Alternatively, both electrode bars 30 and 32 maybe moved toward each other.

Further, as an alternative to the method of removing the metal electrode 28 by applying a high voltage between the electrode bars 30 and 32, the metal electrode 28 may be removed using laser light. For example, the metal electrode 28 can be removed with a laser which is used to form a thin-film solar cell module. Specifically, by emitting laser light from the photovoltaic layer 26 side under the conditions of a wavelength of 532 nm, a frequency of 10 kHz, and power of −0.7 W, and moving the substrate 20 vertically and horizontally to scan the laser light such that the irradiation areas of the laser light overlap, any desired area of the metal electrode 28 can be removed.

The metal electrode 28 may also be removed by blast processing. In blast processing, the metal electrode 28 is removed by the use of mechanical energy by spraying microparticles from a nozzle. It is preferable to use particles of tungsten, alumina, silica, oxidized zirconium, or the like. The particle size to be used is preferably similar to #1000 abrasive. For example, by spraying tungsten particles under the conditions of a spraying pressure of 0.15 MPa and 80 Hz (68 g/minute) and moving the nozzle at a relative velocity of 1.0 m/minute with respect to the substrate 20, an area of the metal electrode 28 applied with the particles can be removed.

Further, the metal electrode 28 may also be removed by etching. For example, by dipping the metal electrode 28 in a water solution prepared by mixing ammonium hydroxide (NH₄OH) diluted by 28% and hydrogen peroxide water (H₂O₂) in the proportion of 2:1, the metal electrode 28 is etched and removed. The area other than that to be removed by etching is preferably protected by a proper resist agent or the like.

Next, a process of modularizing the photovoltaic device will be described with reference to FIG. 7. A copper foil lead (not shown) is attached to the extraction electrode portion A formed in an end part of the substrate 20 by ultrasonic soldering, as an extraction electrode. Then, EVA and backside films (polyethylene terephthalate: PET or the like) are sequentially bonded through vacuum thermal compression by a laminator to form a filled portion 40. The backside film may be made of fluorine resin (ETFE, PVDF), PC, glass, or the like, or may have a structure of sandwiching a metal foil therebetween, or may be metal (steel plate) such as stainless steel, galvalume, or the like, rather than PET. The vacuum thermal compression bonding is preferably performed at 150° C., for example. Further, to crosslink and stabilize the EVA, a heating process is performed at 150° C. for 30 minutes or longer. In addition, a back sheet 42 may also be provided on the filled portion 40. Then, a terminal box 44 is attached to the back surface and a copper foil lead is attached to the terminal box 44 by soldering so as to enable extraction of electrical power from the photovoltaic device. In some cases, the photovoltaic device maybe fitted into a frame 48 made of aluminum, iron, stainless steel or the like with a buffer member 46 such as rubber between them, whereby the module is completed.

Pressure tests were performed on a module applied with the removing process of the metal electrode 28 according to the present embodiment and a module not applied with the removing process, to check the withstanding pressure of the respective modules. The pressure tests were performed in accordance with JIS C 8917.

In the pressure tests, no problem was found in the module to which the removing process of the metal electrode 28 had been applied. However, in the module to which the removing process of the metal electrode 28 had not been applied, overcurrent flowed during voltage application so that the withstanding pressure conditions were not cleared. As a result of examining the module after the test, the part between the extraction electrode portion and the ineffective portion was black, so it was estimated that the current flowed in this part.

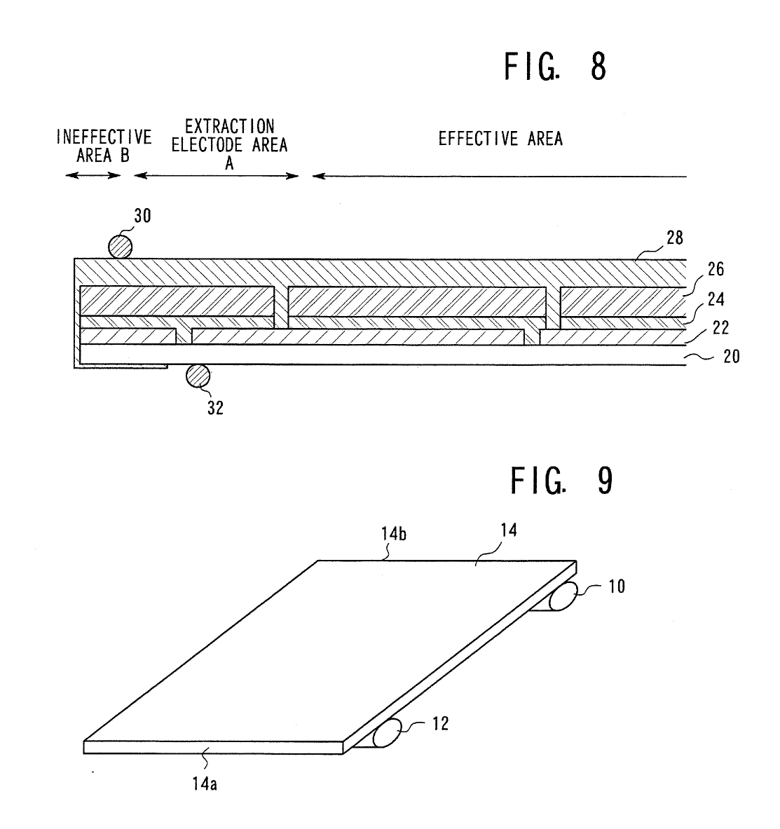

It should be noted that in the present embodiment, although the process of removing the metal electrode 28 is performed after the slits 28a are formed by applying a laser separation process to the metal electrode 28, the removing process may be performed before formation of the slits 28. This means that as shown in FIG. 8, it is acceptable to allow the electrode bar 30 to contact a position serving as the ineffective area B of the photovoltaic device and arrange the electrode bar 32 at a position away from the metal electrode 28 reaching the surface of the substrate 20, and gradually move the electrode bar 32 while applying a voltage.

In general, the slits 28a are formed by allowing laser to enter from the substrate 20 side. If an unnecessary metal electrode 28 is formed on the end part of the substrate 20, there is a case where laser cannot be irradiated to the transparent conductive film 22, the photovoltaic films 24 and 26, and the like under desired conditions due to being obstructed by such metal electrode 28. In that case, it is preferable to remove the metal electrode 28 before formation of the slits 28a.

Further, in the present embodiment, although the case of applying the removing process of the metal electrode 28 to an end part on the positive electrode (+ electrode) side of the photovoltaic device has been described, the process may be applied to the metal electrode 28 of an end part on the negative electrode (− electrode) side or an end part along the slits 22a, 26a, and 28a.

Further, in the present embodiment, although the method of removing the metal electrode 28 reaching the surface side of the substrate 20 has been described, the metal removing method of the present embodiment is applicable in the case where the metal electrode 28 does not reach the surface side of the substrate 20.

For example, even in the case where the metal electrode 28 does not reach the surface side of the substrate 20, by removing the metal electrode 28 on the photovoltaic layer 26 in the ineffective area B at the end part of the substrate 20, the pressure resisting feature between the frame 48 and the photovoltaic device after modularization can be improved.

1. A method for manufacturing a photovoltaic device including one or a plurality of photovoltaic cells, each of the photovoltaic cells including a first electrode layer, a semiconductor layer, and a second electrode layer which are formed on a substrate, the method comprising:
applying a voltage between a first portion of the second electrode layer in which a photovoltaic power is not obtained and a second portion of the second electrode layer which is distant from the first portion, and in which a photovoltaic power is not obtained, so as to remove at least a part of the second electrode layer.

2. The method for manufacturing the photovoltaic device according to claim 1, wherein
the first portion is a portion of the second electrode layer formed on the semiconductor layer side,
the second portion is a portion of the second electrode layer reaching the side opposite to the semiconductor layer, and
at least a part of the second portion is removed.

3. The method for manufacturing the photovoltaic device according to claim 1, wherein
when applying the voltage, the application of the voltage is performed while moving at least one of an electrode for applying a voltage to the first portion and an electrode for applying a voltage to the second portion.

4. The method for manufacturing the photovoltaic device according to claim 1, wherein
the voltage is at least higher than a photovoltaic power of the photovoltaic cell.

5. The method for manufacturing the photovoltaic device according to claim 1, wherein
the application of the voltage is performed using a bar-shaped conductive member.

6. A photovoltaic device comprising one or a plurality of photovoltaic cells, each of the photovoltaic cells including a first electrode layer, a semiconductor layer, and a second electrode layer which are formed on a substrate, wherein
a part of the semiconductor layer is not covered with the second electrode layer.

7. The photovoltaic device according to claim 6, wherein
the second electrode layer on the semiconductor layer in an end part of the substrate is formed in an island shape.
